(19) United States
(12) Patent Application Publication
(10) Pub. No.: US 2026/0129931 A1
(43) Pub. Date: May 7, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Jui-Lin KUO, Hsinchu (TW); Jin CAI, Hsinchu (TW); Wan-Ting KUNG, Hsinchu (TW); Huang-Lin CHAO, Hsinchu (TW); CHIH-HAO WANG, Hsinchu (TW)

(73) Assignee: Taiwan Semiconductor Manufacturing Company, Ltd., Hsinchu (TW)

(21) Appl. No.: 18/937,440

(22) Filed: Nov. 5, 2024

(51) Int. Cl. H01L 29/08; H01L 21/265; H01L 29/06; H01L 29/423; H01L 29/49; H01L 29/775; H01L 29/786

(52) U.S. Cl. CPC H10D 62/151; H10P 30/20; H10D 30/43; H10D 30/6735; H10D 30/6757; H10D 62/121; H10D 64/668

(57) ABSTRACT

A semiconductor structure and a manufacturing method thereof are provided. The manufacturing method of the semiconductor structure includes: epitaxially growing a semiconductor material among at least two channel layers; implanting pnictogen dopants in the semiconductor material; implanting chalcogen dopants in the semiconductor material; annealing the semiconductor material with the chalcogen dopants; forming a bottom contact etching stop layer (BCESL) on the semiconductor material with the chalcogen dopants; and etching the BCESL and forming a metal layer above the semiconductor material.

### BACKGROUND

The disclosure relates in general to a structure of an electronic element and a manufacturing method thereof, and more particularly to a semiconductor structure and a manufacturing method thereof.

Current N-type source-drain implant (pnictogens, e.g., phosphorus and arsenic) suffers from doping limit that carrier concentration does not increase with larger dopant concentration when dopant concentration is larger than 10²¹ cm⁻³.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a stereoscopic view of a semiconductor structure 100 according to one embodiment of the present disclosure.

FIG. 2 shows the section view of the semiconductor structure 100 along an X-cut section line B-B according to one embodiment of the present disclosure.

FIG. 3A shows the relationship between the carrier concentration and the doping concentration for Tellurium (Te), Phosphorus (P), Arsenic (As) and Antimony (Sb) according to one embodiment of the present disclosure.

FIG. 3B shows the relationship between the resistivity and the doping concentration for Tellurium (Te), Phosphorus (P), Arsenic (As) and Antimony (Sb) according to one embodiment of the present disclosure.

FIG. 4 shows the energy state of the pnictogen dopants according to one embodiment of the present disclosure.

FIG. 5 shows the energy state of the chalcogen dopants according to one embodiment of the present disclosure.

FIG. 6 illustrates a manufacturing method of a semiconductor structure whose semiconductor material implanted chalcogen dopants instead of pnictogen dopants according to one embodiment of the present disclosure.

FIG. 7 shows the atom concentration of the semiconductor material implanted chalcogen dopants instead of pnictogen dopants according to one embodiment of the present disclosure.

FIG. 8 shows the carrier density of the semiconductor material implanted chalcogen dopants instead of pnictogen dopants according to one embodiment of the present disclosure.

FIG. 9 illustrates a manufacturing method of a semiconductor structure whose semiconductor material implanted both of pnictogen dopants and chalcogen dopants according to one embodiment of the present disclosure.

FIG. 10 shows the atom concentration of the semiconductor material implanted both of pnictogen dopants and chalcogen dopants according to one embodiment of the present disclosure.

FIG. 11 shows the carrier density of the semiconductor material implanted both of pnictogen dopants and chalcogen dopants according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “comprise,” “comprising,” “include,” “including,” “has,” “having,” etc. used in this specification are open-ended and mean “comprises but not limited.” The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

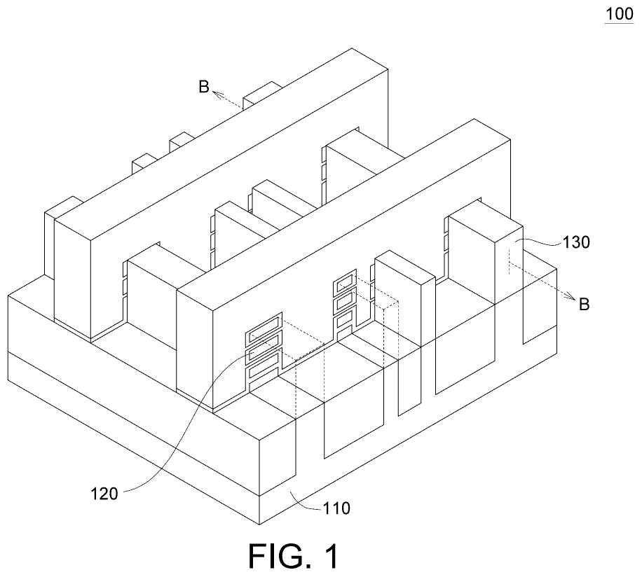

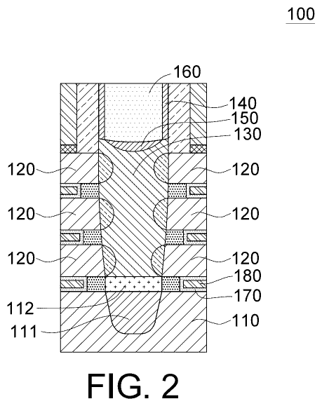

Please refer to FIG. 1 and. FIG. 1 shows a stereoscopic view of a semiconductor structure 100 according to one embodiment of the present disclosure. FIG. 2 shows the section view of the semiconductor structure 100 along an X-cut section line B-B according to one embodiment of the present disclosure. The semiconductor structure 100 is, for example, a gate all around (GAA) structure. As shown in the FIG. 2, the semiconductor structure 100 at least includes a substrate 110, at least two channel layers 120, a semiconductor material 130, a bottom contact etching stop layer (BCESL) 140, a silicide layer 150, a metal layer 160, at least two dielectric layers 170 and at least two metal gates 180.

The channel layers 120 are disposed above the substrate 110. The semiconductor material 130 is disposed among the channel layers 120. The BCESL 140, the silicide layer 150 and the metal layer 160 are disposed on the semiconductor material 130 with the chalcogen dopants.

A conductivity path is formed from the channel layers 120 to the metal layer 160. In order to obtain good electrical conductivity, the researchers work on reducing the contact resistance. In one embodiment, the semiconductor material 130 could be implanted chalcogen dopants, instead of pnictogen dopants. The chalcogen dopants are, for example, Selenium (Se) or Tellurium (Te). In another embodiment, the semiconductor material 130 could be implanted both of pnictogen dopants and chalcogen dopants. The pnictogen dopants are, for example, Phosphorus (P), Arsenic (As) or Antimony (Sb).

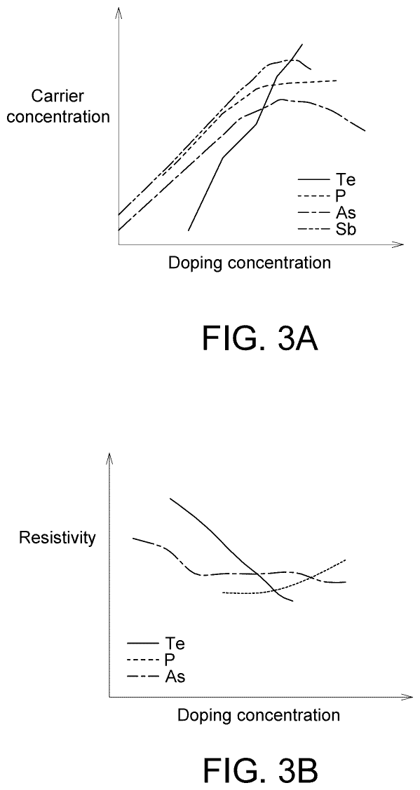

Please refer to FIGS. 3A and 3B. FIG. 3A shows the relationship between the carrier concentration and the doping concentration for Tellurium (Te), Phosphorus (P), Arsenic (As) and Antimony (Sb) according to one embodiment of the present disclosure. FIG. 3B shows the relationship between the resistivity and the doping concentration for Tellurium (Te), Phosphorus (P), Arsenic (As) and Antimony (Sb) according to one embodiment of the present disclosure. To reduce contact resistance, increasing dopant concentration and activation are critical issues. However, for pnictogen element doping (e.g., Phosphorus (P), Arsenic (As) and Antimony (Sb)), carrier concentration decreases when total dopant concentration exceeds 10²¹ cm⁻³, which results in increasing contact resistance. In contract, for chalcogen element doping (e.g., Tellurium (Te)), carrier concentration increases when total dopant concentration exceeds 10²¹ cm⁻³, which results in decreasing contact resistance.

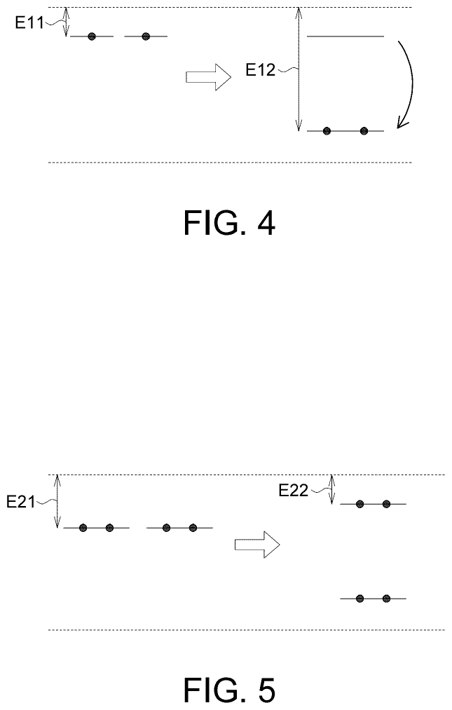

Please refer to FIGS. 4 and 5. FIG. 4 shows the energy state of the pnictogen dopants according to one embodiment of the present disclosure, and FIG. 5 shows the energy state of the chalcogen dopants according to one embodiment of the present disclosure. When the dopant concentration is lower than 10²¹ cm⁻³, the pnictogen dopants have an ionization energy E11 and the chalcogen dopants have an ionization energy E21. Isolated substitutional defect is more likely to form at low dopant concentration. Shallow level impurities (pnictogen dopants) are easier to yield carrier in terms of isolated substitutional defect.

At high dopant concentration, two neighboring substitutional defects (dimer) are energetically favored to form; at this regime, pnictogen dimer constitutes dopant compensator due to vacant metallic-like state and in turn results in pnictogen doping limit. When the dopant concentration is higher than 10²¹ cm⁻³, the pnictogen dopants have an ionization energy E12 and the chalcogen dopants have an ionization energy E22. At high dopant concentration, dimer is more likely to form. Chalcogen dimer is potential doner while pnictogen dimer is dopant compensator. Therefore, for the pnictogen dopants, carrier concentration decreases when total dopant concentration exceeds 10²¹ cm⁻³, which results in increasing contact resistance. In contract, for chalcogen dopants, carrier concentration increases when total dopant concentration exceeds 10²¹ cm⁻³, which results in reducing contact resistance.

For reducing contact resistance, chalcogen dopants are used to be implanted into the semiconductor material 130. In one embodiment, the semiconductor material 130 could be implanted chalcogen dopants, instead of pnictogen dopants. In another embodiment, the semiconductor material 130 could be implanted both of pnictogen dopants and chalcogen dopants.

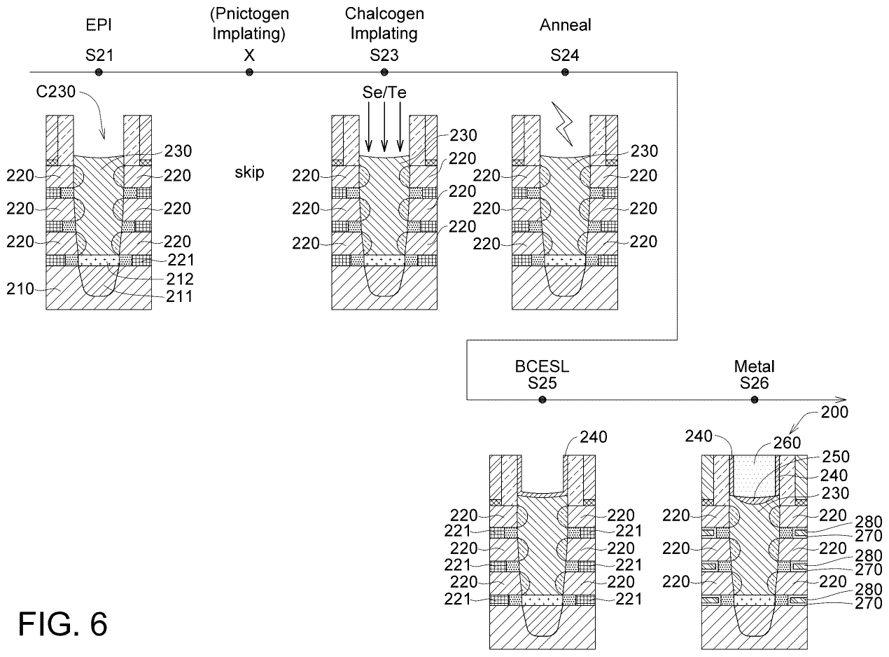

Please refer to FIG. 6, which illustrates a manufacturing method of a semiconductor structure 200 whose semiconductor material 230 implanted chalcogen dopants instead of pnictogen dopants according to one embodiment of the present disclosure. At step S21, the semiconductor material 230 is epitaxially grown among at least two channel layers 220 and over the separation layer 212 and the semiconductor region 211. The semiconductor region 211 may be formed of, for example, silicon (for example, L0 Epitaxy), SiGe, dielectric layer such as SiO2, SiN, etc. The separation layer 212 is also called “flexible bottom isolation/insulator (FBI) layer” or “bottom isolation structure”. The separation layer 212 can be used to increase the isolation between the adjacent two of the semiconductor materials 230 (reducing the current leakage). For example, a concave C230 is defined between the channel layers 220 via lithography process and etching process, and then an N-type material is epitaxially grown in the concave C230 via Liquid Phase Epitaxy (LPE), Solid Phase Epitaxy (SPE) or Vapor Phase Epitaxy (VPE) to form the semiconductor material 230. An epitaxy process may use CVD deposition techniques (for example, VPE and/or UHV-CVD), molecular beam epitaxy, other suitable epitaxial growth processes, or combinations thereof.

At step S23, chalcogen dopants are implanted in the semiconductor material 230. For example, the chalcogen dopants are implanted via ion implantation process. The chalcogen dopants are, for example, Selenium (Se) and/or Tellurium (Te). In one embodiment, Selenium (Se), Tellurium (Te) or combination of Selenium (Se) and Tellurium (Te) could be implanted into the semiconductor material 230. In this step, a process energy is, for example, controlled at 1 to 3 keV and dose of the chalcogen dopants is, for example, controlled at 2e15 to 2e16 cm⁻². After the step S23 of implanting the chalcogen dopants, a dopant concentration of the chalcogen dopants exceeds 10²¹ cm⁻³.

Next, at step S24, the semiconductor material 230 with the chalcogen dopants is annealed. For example, the semiconductor material 230 with the chalcogen dopants could be annealed via rapid thermal annealing (RTA) and/or laser annealing.

Then, at step S25, a bottom contact etching stop layer (BCESL) 240 is formed on the semiconductor material 230 with the chalcogen dopants. The bottom contact etching stop layer (BCESL) 240 is formed, for example, by Plasma Enhanced Chemical Vapor Deposition (PECVD), Plasma Enhanced Atomic Layer Deposition (PEALD), spin coating, remote plasma Chemical Vapor Deposition (CVD), remote plasma Physical Vapor Deposition (PVD) or other suitable process. The bottom contact etching stop layer (BCESL) 240 could be Silicon carbon nitride (SiCxNy), Boron Nitride (BN), Boron carbonitride (BCN), silicon oxycarbonitride (SiOCN), and/or silicon oxycarbide (SiOC).

After the step S25, the SiGe layers 221 are replaced by the dielectric layers 270 and the metal gates 280. Afterwards, at step S26, the BCESL 240 is etched, and the silicide layer 250 and the metal layer 260 are formed on the semiconductor layer 230. The metal layer 260 could be formed, for example, by Electro Chemical Plating (ECP), Electroless Deposition (ELD), Chemical Vapor Deposition (CVD), Physical Vapor Deposition (PVD), plating or other suitable processes. The material of the metal layer 260 is Titanium (Ti), titanium nitride (TiN), Platinum (Pt), W (tungsten), Cobalt (Co), Ruthenium (Ru), Tungsten (W), Iridium (Ir), Rhodium (Rh), Tantalum nitride (TaN), Copper (Cu), the like, or the combination thereof.

In the manufacturing method shown in the FIG. 6, the semiconductor material 230 is implanted chalcogen dopants, instead of pnictogen dopants. That is, the step of implanting Pinctogen dopants is skipped.

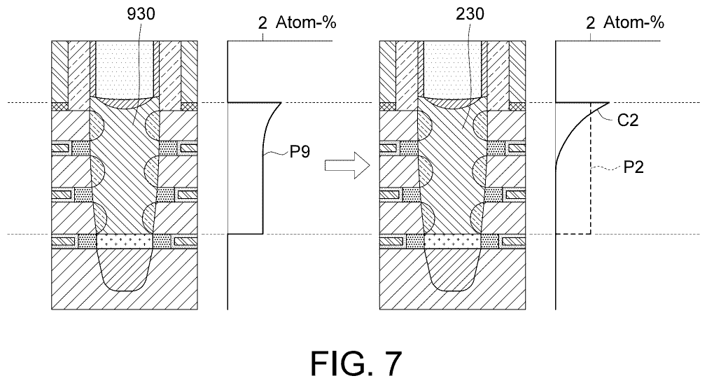

Please refer to FIG. 7, which shows the atom concentration of the semiconductor material 230 according to one embodiment of the present disclosure. As shown in the left drawing of the FIG. 7, a pnictogen atom concentration curve P9 of the semiconductor material 930 implanted pnictogen dopants is shown. The pnictogen atoms in the semiconductor material 930 are formed via the epitaxial growing and the pnictogen implanting.

As shown in the right drawing of the FIG. 7, a chalcogen atom concentration curve C2 and a pnictogen atom concentration curve P2 of the semiconductor material 230 implanted chalcogen dopants are shown. The chalcogen atoms in the semiconductor material 230 are formed via the chalcogen implanting, and the pnictogen atoms in the semiconductor material 230 are formed via the epitaxial growing.

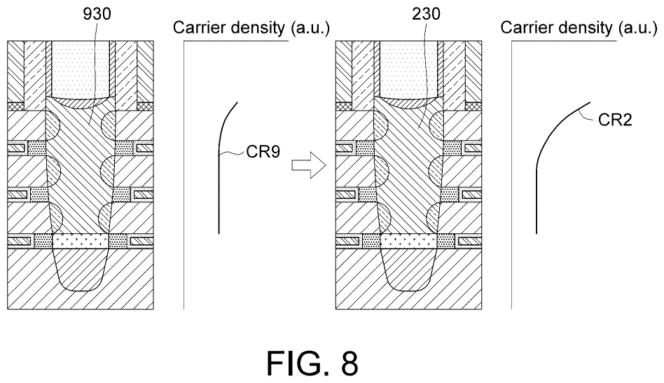

Please refer to FIG. 8, which shows the carrier density of the semiconductor material 230 according to one embodiment of the present disclosure. As shown in the left drawing of the FIG. 8, a carrier density curve CR9 of the semiconductor material 930 implanted pnictogen dopants is shown. The carriers in the semiconductor material 930 are only provided from the pnictogen atoms.

As shown in the right drawing of the FIG. 8, a carrier density curve CR2 of the semiconductor material 230 implanted chalcogen dopants is shown. The carriers in the semiconductor material 230 are mainly provided from the chalcogen atoms. When total dopant concentration exceeds 10²¹ cm⁻³, carrier concentration provided from the chalcogen dopants would be increased and results in decreasing contact resistance.

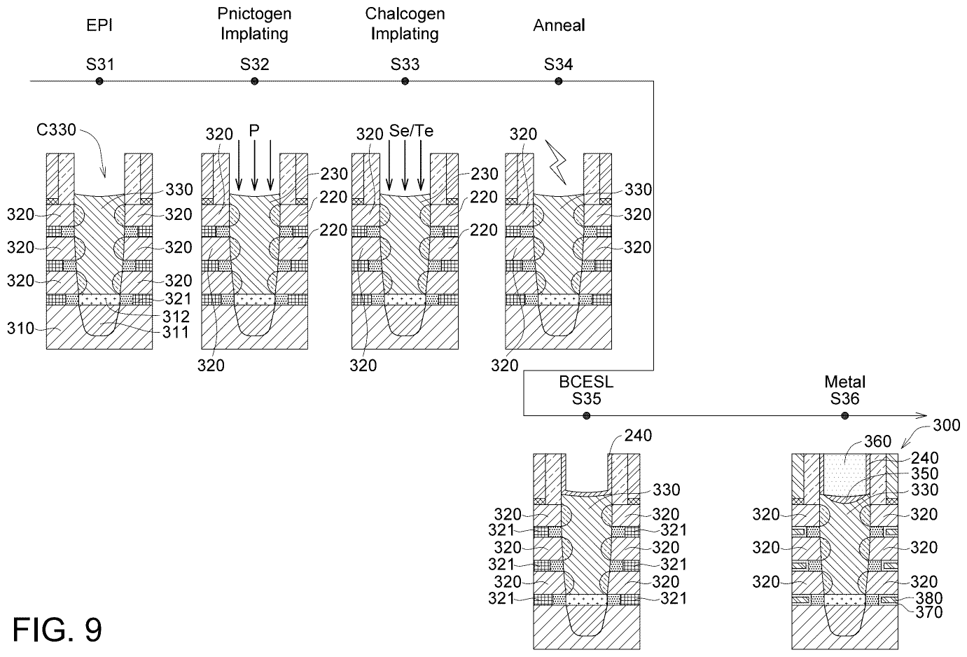

Please refer to FIG. 9, which illustrates a manufacturing method of a semiconductor structure 300 whose semiconductor material 330 implanted both of pnictogen dopants and chalcogen dopants according to one embodiment of the present disclosure. At step S31, the semiconductor material 330 is epitaxially grown among at least two channel layers 320 and over the separation layer 312 and the semiconductor region 311. The semiconductor region 311 may be formed of, for example, silicon (for example, L0 Epitaxy), SiGe, dielectric layer such as SiO2, SiN, etc. The separation layer 312 is also called “FBI layer” or “bottom isolation structure”. The separation layer 312 is used to increase the isolation between the adjacent two of the semiconductor materials 330 (reducing the current leakage). For example, a concave C330 is defined among the channel layers 320 is defined via lithography process and etching process, then an N-type material is epitaxially grown in the concave C330 via Liquid Phase Epitaxy (LPE), Solid Phase Epitaxy (SPE) or Vapor Phase Epitaxy (VPE) to form the semiconductor material 330. An epitaxy process can use CVD deposition techniques (for example, VPE and/or UHV-CVD), molecular beam epitaxy, other suitable epitaxial growth processes, or combinations thereof.

At step S32, pnictogen dopants are implanted in the semiconductor material 230. For example, the pnictogen dopants are implanted via ion implantation process. The pnictogen dopants are, for example, Phosphorus (P), Arsenic (As) or Antimony (Sb). In one embodiment, Phosphorus (P), Arsenic (As), Antimony (Sb) or combination of Phosphorus (P), Arsenic (As) and Antimony (Sb) could be implanted into the semiconductor material 330. In this step, a process energy is, for example, controlled at 1 to 3 keV and dose of the pnictogen dopants is, for example, controlled at 2e15 to 2e16 cm⁻².

At step S33, chalcogen dopants are implanted in the semiconductor material 330. For example, the chalcogen dopants are implanted via ion implantation process. The chalcogen dopants are, for example, Selenium (Se) and/or Tellurium (Te). In one embodiment, Selenium (Se), Tellurium (Te) or combination of Selenium (Se) and Tellurium (Te) could be implanted into the semiconductor material 330. In this step, a process energy is, for example, controlled at 1 to 3 keV and dose of the chalcogen dopants is, for example, controlled at 2e15 to 2e16 cm⁻². After the step S33 of implanting the chalcogen dopants, a dopant concentration of the chalcogen dopants exceeds 10²¹ cm⁻³.

Next, at step S34, the semiconductor material 330 with the chalcogen dopants is annealed. For example, the semiconductor material 330 with the pnictogen dopants and the chalcogen dopants could be annealed via rapid thermal annealing (RTA) and/or laser annealing.

Then, at step S35, a bottom contact etching stop layer (BCESL) 340 is formed on the semiconductor material 330 with the chalcogen dopants. The bottom contact etching stop layer (BCESL) 340 is formed, for example, by Plasma Enhanced Chemical Vapor Deposition (PECVD), Plasma Enhanced Atomic Layer Deposition (PEALD), spin coating, remote plasma Chemical Vapor Deposition (CVD), remote plasma Physical Vapor Deposition (PVD) or other suitable process. The bottom contact etching stop layer (BCESL) 340 could be Silicon carbon nitride (SiCxNy), Boron Nitride (BN), Boron carbonitride (BCN), silicon oxycarbonitride (SiOCN), and/or silicon oxycarbide (SiOC).

After the step S35, the SiGe layers 321 are replaced by the dielectric layers 370 and the metal gates 350. Afterwards, at step S36, the BCESL 340 is etched, and the silicide layer 350 and the metal layer 360 are formed on the semiconductor material 330. The metal layer 360 could be formed, for example, by Electro Chemical Plating (ECP), Electroless Deposition (ELD), Chemical Vapor Deposition (CVD), Physical Vapor Deposition (PVD), plating or other suitable processes. The material of the metal layer 360 is Titanium (Ti), titanium nitride (TiN), Platinum (Pt), W (tungsten), Cobalt (Co), Ruthenium (Ru), Tungsten (W), Iridium (Ir), Rhodium (Rh), Tantalum nitride (TaN), Copper (Cu), the like, or the combination thereof.

In the manufacturing method shown in the FIG. 9, the semiconductor material 330 is implanted both of pnictogen dopants and chalcogen dopants. The step S32 of implanting the pnictogen dopants could be performed before the step S33 of implanting the chalcogen dopants. In another embodiment, the step S32 of implanting the pnictogen dopants could be performed after the step S33 of implanting the chalcogen dopants.

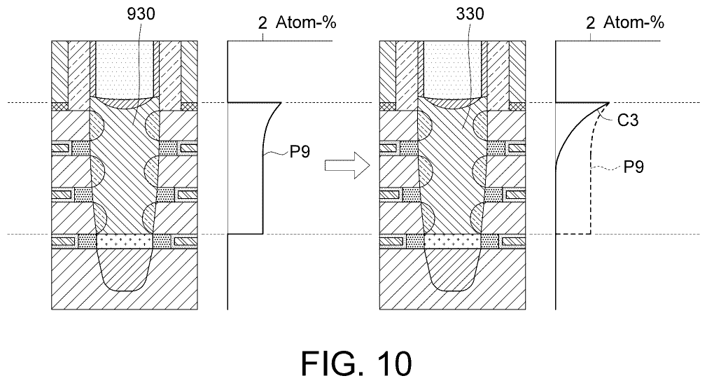

Please refer to FIG. 10, which shows the atom concentration of the semiconductor material 330 according to one embodiment of the present disclosure. As shown in the left drawing of the FIG. 10, the pnictogen atom concentration curve P9 of the semiconductor material 930 implanted pnictogen dopants is shown. The pnictogen atoms in the semiconductor material 930 are formed via the epitaxial growing and the pnictogen implanting.

As shown in the right drawing of the FIG. 10, the pnictogen atom concentration curve P9 and a chalcogen atom concentration curve C3 of the semiconductor material 330 implanted both of the pnictogen dopants and the chalcogen dopants are shown. The pnictogen atoms in the semiconductor material 330 are formed via the epitaxial growing and the pnictogen implanting, and the chalcogen atoms in the semiconductor material 330 are formed via the chalcogen implanting.

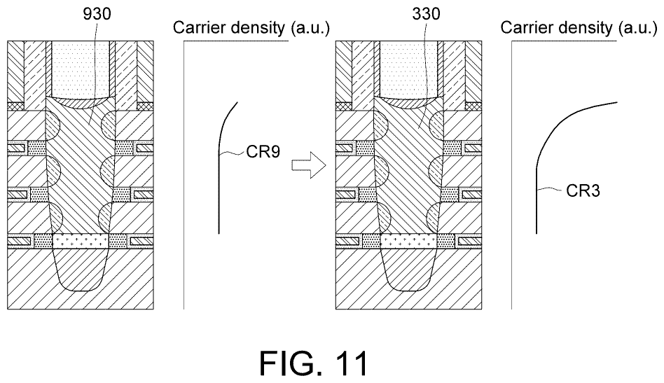

Please refer to FIG. 11, which shows the carrier density of the semiconductor material 330 according to one embodiment of the present disclosure. As shown in the left drawing of the FIG. 11, the carrier density curve CR9 of the semiconductor material 930 implanted pnictogen dopants is shown. The carriers in the semiconductor material 930 are only provided from the pnictogen atoms.

As shown in the right drawing of the FIG. 11, a carrier density curve CR3 of the semiconductor material 330 implanted both of pnictogen dopants and chalcogen dopants is shown. The carriers in the semiconductor material 330 are provided from the pnictogen atoms and the chalcogen atoms. When total dopant concentration exceeds 10²¹ cm⁻³, even if carrier concentration provided from the pnictogen dopants would be decreased, the chalcogen dopants would be increased and results in decreasing contact resistance.

Based on the description described above, the chalcogen implant is used for NFET contact resistance reduction. Raising dopant activation and resulting carrier concentration are essential for reducing contact resistance. Unlike pnictogens, chalcogens, e.g., selenium (Se) and tellurium (Te) can still yield carriers at the regime where dimer population dominates due to occupied metallic-like states.

Further, by replacing phosphorus N-type source-drain implant with chalcogen implant or adopting co-doping (phosphorus and chalcogen) scheme, higher carrier concentration can be obtained with same total dopant concentration, which offers an opportunity to go beyond N-type doping limit of pnictogens and enable further contact resistance reduction.

According to one example embodiment, a manufacturing method of a semiconductor structure is provided. The manufacturing method of the semiconductor structure includes: epitaxially growing a semiconductor material among at least two channel layers; implanting chalcogen dopants in the semiconductor material; annealing the semiconductor material with the chalcogen dopants; forming a bottom contact etching stop layer (BCESL) on the semiconductor material with the chalcogen dopants; and etching the BCESL and forming a metal layer above the semiconductor material.

Based on the semiconductor method of the semiconductor structure described in the previous embodiments, during the step of implanting the chalcogen dopants, a process energy is controlled at 1 to 3 keV.

Based on the semiconductor method of the semiconductor structure described in the previous embodiments, during the step of implanting the chalcogen dopants, dose of the chalcogen dopants is controlled at 2e15 to 2e16 cm⁻².

Based on the semiconductor method of the semiconductor structure described in the previous embodiments, during the step of implanting the chalcogen dopants, the chalcogen dopants are Selenium (Se) or Tellurium (Te).

Based on the semiconductor method of the semiconductor structure described in the previous embodiments, after the step of implanting the chalcogen dopants, a dopant concentration of the chalcogen dopants exceeds 10²¹ cm⁻³.

According to another example embodiment, a manufacturing method of a semiconductor structure is provided. The manufacturing method of the semiconductor structure includes: epitaxially growing a semiconductor material among at least two channel layers; implanting pnictogen dopants in the semiconductor material; implanting chalcogen dopants in the semiconductor material; annealing the semiconductor material with the chalcogen dopants; forming a bottom contact etching stop layer (BCESL) on the semiconductor material with the chalcogen dopants; and etching the BCESL and forming a metal layer above the semiconductor material.

Based on the semiconductor method of the semiconductor structure described in the previous embodiments, during the step of implanting the chalcogen dopants, a process energy is controlled at 1 to 3 keV.

Based on the semiconductor method of the semiconductor structure described in the previous embodiments, during the step of implanting the chalcogen dopants, dose of the chalcogen dopants is controlled at 2e15 to 2e16 cm⁻².

Based on the semiconductor method of the semiconductor structure, during the step of implanting the chalcogen dopants, the chalcogen dopants are Selenium (Se) or Tellurium (Te).

Based on the semiconductor method of the semiconductor structure described in the previous embodiments, after the step of implanting the chalcogen dopants, a dopant concentration of the chalcogen dopants exceeds 10²¹ cm⁻³.

Based on the semiconductor method of the semiconductor structure described in the previous embodiments, the step of implanting the chalcogen dopants is performed after the step of implanting pnictogen dopants.

Based on the semiconductor method of the semiconductor structure described in the previous embodiments, the step of implanting the chalcogen dopants is performed before the step of implanting pnictogen dopants.

Based on the semiconductor method of the semiconductor structure described in the previous embodiments, during the step of implanting the pnictogen dopants, a process energy is controlled at 1 to 3 keV.

Based on the semiconductor method of the semiconductor structure described in the previous embodiments, during the step of implanting the pnictogen dopants, dose of the pnictogen dopants is controlled at 2e15 to 2e16 cm⁻².

Based on the semiconductor method of the semiconductor structure described in the previous embodiments, during the step of implanting the pnictogen dopants, the pnictogen dopants are Phosphorus (P), Arsenic (As) or Antimony (Sb).

Based on the semiconductor method of the semiconductor structure described in the previous embodiments, after the step of implanting the pnictogen dopants, a dopant concentration of the pnictogen dopants exceeds 10²¹ cm⁻³.

According to another example embodiment, a semiconductor structure is provided. The semiconductor structure includes a substrate, at least two channel layers, a semiconductor material, a bottom contact etching stop layer (BCESL) and a metal layer. The at least two channel layers are disposed above the substrate. The semiconductor material is disposed among the channel layers. The semiconductor material has chalcogen dopants. The bottom contact etching stop layer (BCESL) is disposed on the semiconductor material with the chalcogen dopants. The metal layer is disposed above the semiconductor material.

Based on the semiconductor structure described in the previous embodiments, the semiconductor material further has pnictogen dopants.

Based on the semiconductor structure described in the previous embodiments, the chalcogen dopants are Selenium (Se) or Tellurium (Te).

Based on the semiconductor structure described in the previous embodiments, wherein a dopant concentration of the chalcogen dopants exceeds 10²¹ cm⁻³.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method of a semiconductor structure, comprising:
epitaxially growing a semiconductor material among at least two channel layers;
implanting chalcogen dopants in the semiconductor material;
annealing the semiconductor material with the chalcogen dopants;
forming a bottom contact etching stop layer (BCESL) on the semiconductor material with the chalcogen dopants; and
etching the BCESL and forming a metal layer above the semiconductor material.

2. The semiconductor method of the semiconductor structure according to claim 1, wherein during the step of implanting the chalcogen dopants, a process energy is controlled at 1 to 3 keV.

3. The semiconductor method of the semiconductor structure according to claim 1, wherein during the step of implanting the chalcogen dopants, dose of the chalcogen dopants is controlled at 2e15 to 2e16 cm⁻².

4. The semiconductor method of the semiconductor structure according to claim 1, wherein during the step of implanting the chalcogen dopants, the chalcogen dopants are Selenium (Se) or Tellurium (Te).

5. The semiconductor method of the semiconductor structure according to claim 1, wherein after the step of implanting the chalcogen dopants, a dopant concentration of the chalcogen dopants exceeds 10²¹ cm⁻³.

6. A manufacturing method of a semiconductor structure, comprising:
epitaxially growing a semiconductor material among at least two channel layers;
implanting pnictogen dopants in the semiconductor material;
implanting chalcogen dopants in the semiconductor material;
annealing the semiconductor material with the chalcogen dopants;
forming a bottom contact etching stop layer (BCESL) on the semiconductor material with the chalcogen dopants; and
etching the BCESL and forming a metal layer above the semiconductor material.

7. The semiconductor method of the semiconductor structure according to claim 6, wherein during the step of implanting the chalcogen dopants, a process energy is controlled at 1 to 3 keV.

8. The semiconductor method of the semiconductor structure according to claim 6, wherein during the step of implanting the chalcogen dopants, dose of the chalcogen dopants is controlled at 2e15 to 2e16 cm⁻².

9. The semiconductor method of the semiconductor structure according to claim 6, wherein during the step of implanting the chalcogen dopants, the chalcogen dopants are Selenium (Se) or Tellurium (Te).

10. The semiconductor method of the semiconductor structure according to claim 6, wherein after the step of implanting the chalcogen dopants, a dopant concentration of the chalcogen dopants exceeds 10²¹ cm⁻³.

11. The semiconductor method of the semiconductor structure according to claim 6, wherein the step of implanting the chalcogen dopants is performed after the step of implanting pnictogen dopants.

12. The semiconductor method of the semiconductor structure according to claim 6, wherein the step of implanting the chalcogen dopants is performed before the step of implanting pnictogen dopants.

13. The semiconductor method of the semiconductor structure according to claim 6, wherein during the step of implanting the pnictogen dopants, a process energy is controlled at 1 to 3 keV.

14. The semiconductor method of the semiconductor structure according to claim 6, wherein during the step of implanting the pnictogen dopants, dose of the pnictogen dopants is controlled at 2e15 to 2e16 cm⁻².

15. The semiconductor method of the semiconductor structure according to claim 6, wherein during the step of implanting the pnictogen dopants, the pnictogen dopants are Phosphorus (P), Arsenic (As) or Antimony (Sb).

16. The semiconductor method of the semiconductor structure according to claim 6, wherein after the step of implanting the pnictogen dopants, a dopant concentration of the pnictogen dopants exceeds 10²¹ cm⁻³.

17. A semiconductor structure, comprising:
a substrate;
at least two channel layers, disposed above the substrate;
a semiconductor material, disposed among the channel layers, wherein the semiconductor material has chalcogen dopants;
a bottom contact etching stop layer (BCESL), disposed on the semiconductor material with the chalcogen dopants; and
a metal layer, disposed above the semiconductor material.

18. The semiconductor structure according to claim 17, wherein the semiconductor material further has pnictogen dopants.

19. The semiconductor structure according to claim 17, wherein the chalcogen dopants are Selenium (Se) or Tellurium (Te).

20. The semiconductor structure according to claim 17, wherein a dopant concentration of the chalcogen dopants exceeds 10²¹ cm⁻³.
